(19) United States
(12) Patent Application Publication
(10) Pub. No.: US 2006/0153405 A1
(43) Pub. Date: Jul. 13, 2006

(54) Audio automatic volume control

(76) Inventor: Bruce A. Myers, Kokomo, IN (US)

Correspondence Address: DELPHI TECHNOLOGIES, INC., M/C 480-410-202, PO BOX 5052, TROY, MI, 48007, US

(21) Appl. No.: 11/035,208

(22) Filed: Jan. 13, 2005

(51) Int. Cl. H03G 3/00

(52) U.S. Cl. 381/107; 381/104

(57) ABSTRACT

An audio volume control system including a plurality of audio signal sources each configured to generate an audio signal, and a controller configured to retrieve a stored volume setting for each audio signal source and control the output volume level of an output device in response to the stored volume setting.

### TECHNICAL BACKGROUND

The present invention relates generally to an audio control system and, more particularly, to a system for controlling audio volume based on a selected audio signal source.

### BACKGROUND OF THE INVENTION

Existing audio systems often include a plurality of audio signal sources from which a user may select to supply an audio signal to control an output speaker. Large variations in output levels may occur when the audio signal source is changed by the user, thereby resulting in large variations in initial speaker volume. For example, such audio systems do not effectively compensate for the potential large change in audio volume from a weak radio station to a compact disk (CD) player. This problem is also noticeable when switching between weak and strong radio stations. These large variations in speaker volume can generate discomfort for the listener and may require the listener to manually adjust the volume for each station or audio source selected.

As noted above, in order to compensate for large variations in speaker volume when changing audio signal sources, the user may manually adjust the current volume control setting. Alternatively, the signal strength supplied to the speakers could be measured and the volume adjusted in response thereto. However, normal variations in music dynamics would cause variations in speaker signal strength. As such, any automatic control based on speaker signal strength would likely eliminate the effect of normal musical dynamics and significantly reduce the quality of the musical selection.

A further alternative is to measure the incoming wireless signal strength and adjust the volume based on the current volume control setting. However, normal variations in signal strength make this difficult and wireless signal strength does not apply to CD or cassette tape audio source signals.

For automobile applications, the volume could be changed based upon the speed of the vehicle. While this method is known in the art, it does not solve the problem of large variations in speaker volume when the audio signal source is changed.

It is also known to adjust volume based on the time of dusk and dawn for a given day, to account for variations in radio frequency strength during different times of the day. However, this does not solve the basic problem of audio volume control detailed herein.

### SUMMARY OF THE INVENTION

According to an illustrative embodiment of the present invention, an audio volume control system includes an output device, a plurality of audio signal sources, and a source selector coupled to the plurality of audio signal sources and configured to connect one of the audio signal sources to the output device in response to input from a user. A controller is coupled to the output device and is configured to identify the audio signal source connected to the output device. A memory is configured to store the identity of the audio signal source connected to the output device and an output volume level of the output device as a stored volume setting for the audio signal source. The controller is further configured to retrieve the stored volume setting for the audio signal source, and control the output volume level of the output device in response to the stored volume setting.

In another illustrative embodiment of the present invention, an audio volume control system includes an audio signal source, a volume selector configured to control the output volume level from an audio signal supplied by the audio signal source in response to input from a user, and a processor configured to identify the audio signal source and the output volume level of the audio signal. A clock is in communication with the processor, wherein the processor is configured to associate the output volume level of the audio signal with the audio signal source after the clock has counted a predetermined number of increments.

According to yet another illustrative embodiment of the present invention, a method of automatically controlling the volume produced by an audio system includes selecting a first audio signal source configured to generate a first audio signal, and identifying the first audio signal source. The method further includes the step of controlling an output volume level of an output device in response to a first stored volume setting associating the first audio signal source with a first output volume level. The method also includes the steps of selecting a second audio signal source configured to generate a second audio signal, identifying the second audio signal source, and controlling an output volume level of the output device in response to a second stored volume setting associating the second audio signal source with a second output volume level.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1 is a block diagram illustrating various communication links within the audio volume control system in accordance with an illustrative embodiment of the present invention;

FIG. 2 is a flow chart of an illustrative method of operation for applying a volume setting in accordance with the audio volume control system of FIG. 1;

FIG. 3 is a flow chart of an illustrative method of operation for storing a volume setting in accordance with the audio volume control system of FIG. 1; and

FIG. 4 is a illustrative embodiment look-up table of stored volume settings for use in connection with the audio volume control system of FIG. 1.

Corresponding reference characters indicate corresponding parts throughout the several views. Although the drawings represent embodiments of the present invention, the drawings are not necessarily to scale and certain features may be exaggerated in order to better illustrate and explain the present invention. The exemplifications set out herein illustrate embodiments of the invention in several forms and such exemplification is not to be construed as limiting the scope of the invention in any manner.

### DESCRIPTION OF INVENTION

The embodiments discussed below are not intended to be exhaustive or limit the invention to the precise forms disclosed in the following detailed description. Rather, the embodiments are chosen and described so that others skilled in the art may utilize their teachings.

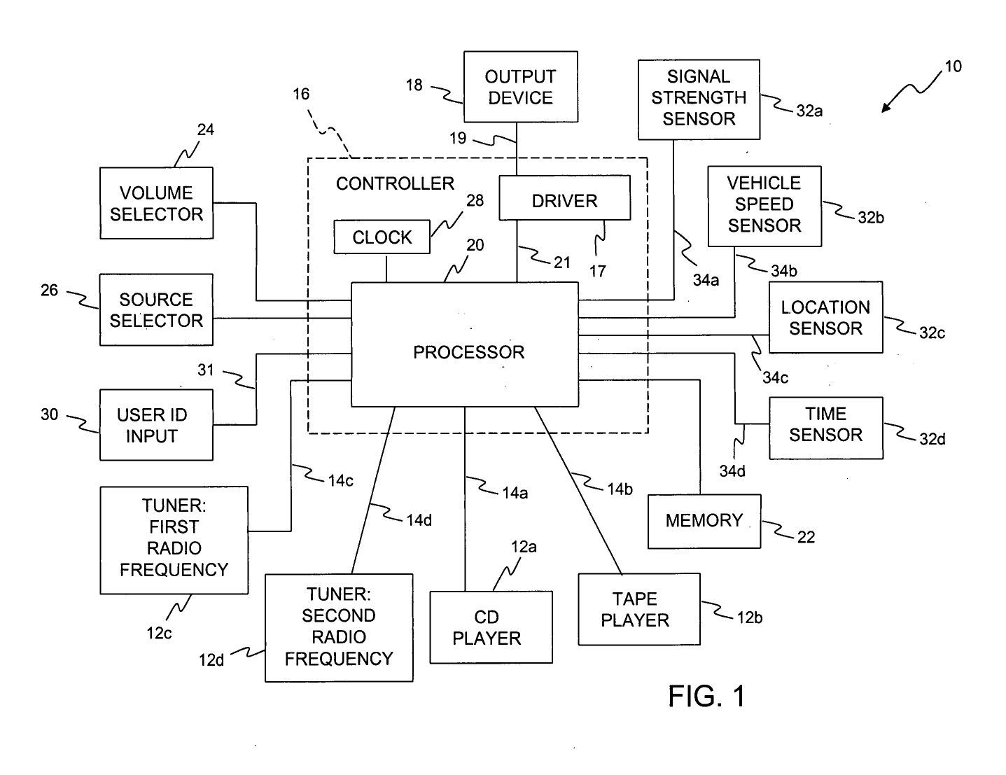

Referring initially to FIG. 1, an audio volume control system 10 according to an illustrative embodiment of the present invention includes a plurality of audio signal sources 12 each configured to generate an audio signal 14. The audio signal sources 12 may include conventional audio devices such as a compact disk (CD) player 12a and a cassette tape player 12b. Similarly, the audio signal sources may include the plurality of radio stations or frequencies received by a conventional radio or tuner. More particularly, as illustrated in FIG. 1, each frequency received by the tuner comprises a separate and distinct audio signal source 12. As such, a first radio frequency 12c comprises a audio signal source independent from a second radio frequency 12d. While only two radio frequencies 12c, 12d are shown in FIG. 1, it should be appreciated that this does not limit the scope of the invention and that any number of radio frequencies may be utilized in connection with the audio volume control system 10. It should be further noted that additional audio signal sources 12, such as MP3 players and DVD players, may be used in connection with the system 10.

The audio signals 14a, 14b, 14c, 14d generated by the audio signal sources 12a, 12b, 12c, 12d are supplied to a controller 16. The controller 16 is coupled to a driver 17 which, in turn, is coupled to an output device 18, illustratively one or more conventional audio speakers. The driver 17 illustratively comprises a conventional output device driver circuit which provides the drive current or signal 19 required to generate audio power at the output device 18. In other words, the controller 16 controls the output volume level by adjusting the output 19 from the output device driver circuit 17 to the output device 18. In the illustrative embodiment, the controller 16 includes a processor 20 configured to transmit an output or control signal 21 to the driver 17 in response to the audio signal 14 from a selected one of the audio signal sources 12. In response to the control signal 21, the driver 17 causes the output device 18 to generate sound at a predetermined output volume level as further detailed herein. While FIG. 1 illustrates the driver 17 as part of the controller 16, it should be appreciated that in alternative embodiments, the driver 17 may be part of the output device 18, or independent from both the processor 20 and the output device 18.

The processor 20 may be of conventional design, such as a CPU. The processor 20 illustratively couples to a memory 22 which may include, for example, volatile memory (such as RAM) and non-volatile memory (such as ROM, PROM, and EE PROM). The memory 22 may be utilized to provide instructions to the processor 20 and to store volume settings for the audio signal sources 12 as detailed below.

A volume selector 24, such as a conventional rotary control knob, is operably coupled to the processor 20. The volume selector 24 is configured to permit the user to manually control the drive signal 18 delivered to the output device 18, thereby controlling the output volume level of sound from the output device 18. A source selector 26 is operably coupled to the processor 20, and illustratively comprises a plurality of push buttons which may be manually depressed by the user to select one of the plurality of audio signal sources 12. The source selector 26 is configured to permit the user to place one of the audio signal sources 12 in communication with the output device 18 for receipt of an audio signal 14 thereby. Illustratively, a clock 28 is operably coupled with the processor 20 and may be of conventional design for counting a successive number of time increments. The clock 28 may form a portion of the controller 16 or be independent therefrom.

A user identification (ID) input 30 is illustratively provided in communication with the processor 20 and is configured to accept input in order to identify the current user or operator of the audio signal sources 12 and provide a signal 31 indicative thereof to the processor 20. The user ID input 30 may comprise conventional push buttons located adjacent the audio signal sources 12. Alternatively, the user ID input 30 may be integral with a conventional remote access device, such as a key fob, utilized with a vehicle. In such a case, multiple access devices are provided wherein each access device has a different identification code or signal associated with its user.

A plurality of external condition sensors 32 may be operably coupled to the processor 20 and are configured to detect conditions external to the audio signal sources 12. As illustrated in FIG. 1, the external condition sensors may include a signal strength sensor 32a, which is configured to detect the strength of an incoming wireless signal, such as the first or second radio frequencies 12c, 12d. In response to a signal 34a from the signal strength sensor 32a, the processor 20 adjusts the output volume level of the output device 18. In other words, the processor 20 increases the volume of the output device 18 in response to a weak incoming wireless signal 12c, 12d, and decrease the volume of the output device 18 in response to a strong incoming wireless signal 12c, 12d.

Another illustrative external condition sensor comprises a vehicle speed sensor 32b, which detects the speed of a vehicle and provides a signal 34b indicative thereof to the processor 20. In response to the signal 34b, the processor 20 changes the output volume level of the output device 18. In other words, the processor 20 increase the volume of the output device 18 in response to increased vehicle speed, and decreases the volume of the output device 18 in response to decreased vehicle speed. A location sensor 32c may also be operably coupled to the processor 20 and is configured to detect the position of the audio signal sources 12 and provide a signal 34c indicative thereof to the processor 20. The processor 20, in turn, adjusts the volume setting based upon the detected location. For example, in order to compensate for greater distances of the tuner from the transmitter supplying the desired radio frequency 12c, 12d, the processor 20 increases the output volume level of the output device 18. Another illustrative external condition sensor comprises a time sensor 32d which supplies a signal 34d configured to cause the processor 20 to adjust the output volume level of the output device 18 based upon the time of day in order to compensate for different radio frequency strengths during different times of the day. It should be noted that the time sensor 32d may comprise the clock 28 or be independent thereof.

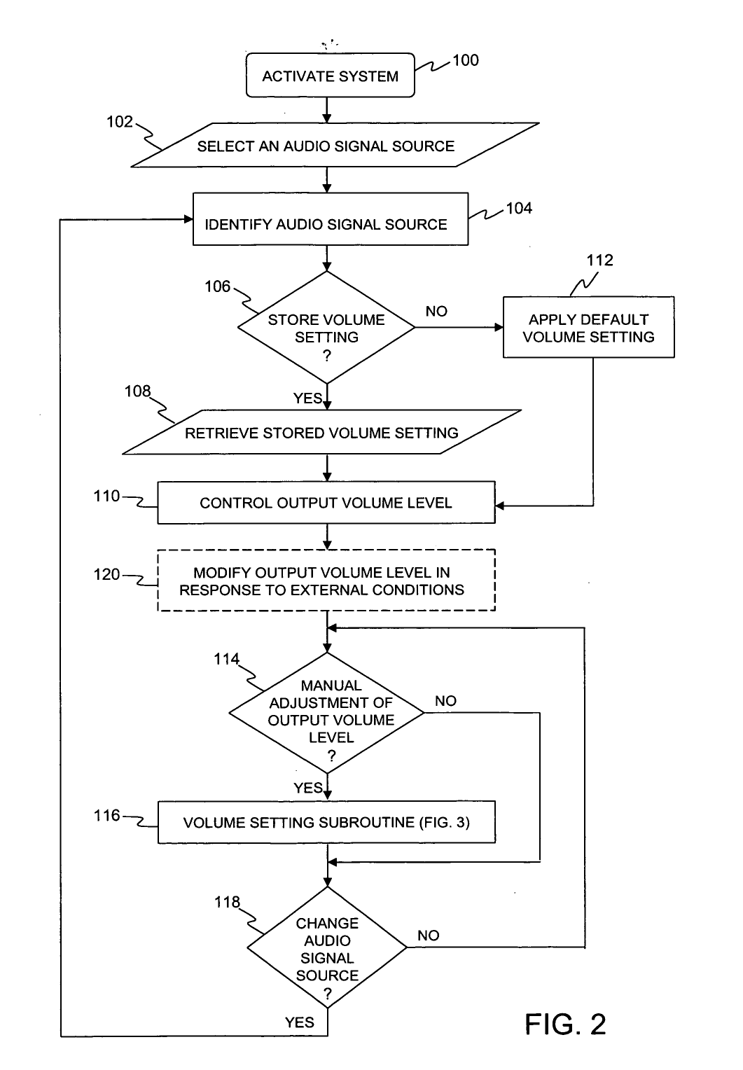

Turning now to FIG. 2, operation of the audio volume control system 10 begins with a user activating the system 10 as shown in block 100. Next, the user selects an audio signal source 12 by operating the source selector 26 at block 102. The controller 16 identifies the audio signal source 12 at block 104 and then determines whether a volume setting for the source 12 has been stored in memory 22 at block 106. As detailed herein, each volume setting includes an output volume level and an associated audio signal source 12. If a volume setting has been stored in memory 22, the process continues to block 108 where the controller 16 retrieves the stored volume setting from memory 22. Next, the controller 16 controls the output volume level of the output device 18 at block 110.

If no stored volume setting is present at block 106, the controller 16 applies a default volume setting at block 112. In one embodiment, the default volume setting is a null value for the output volume levels for all audio signal sources 12. In an alternative embodiment, the default volume setting for each audio signal source 12 is an initial default output volume level stored in memory 22, which may be independent from initial default output volume levels of the other audio signal sources 12.

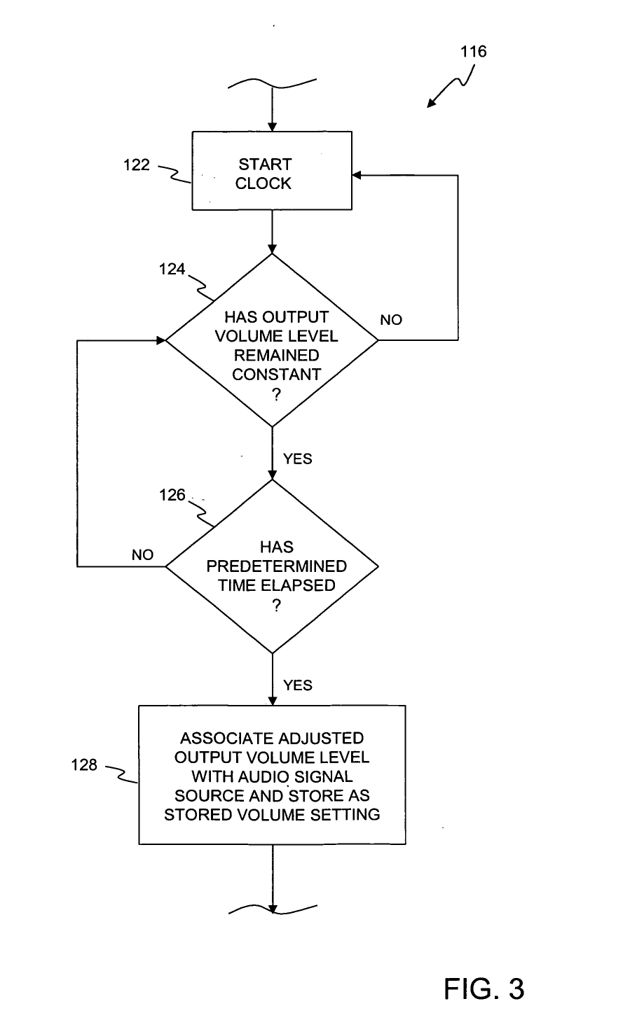

The process continues at decision block 114 where the controller 16 queries whether there has been a manual adjustment of the output volume level through the volume selector 24. If there has been a manual adjustment, the process continues at a volume setting sub-routine 116 as detailed below in connection with FIG. 3. If there has been no manual adjustment of the output level, the process continues directly to decision block 118. At decision block 118, the controller 16 decides whether there has been a change of audio signal source 12 through the source selector 26. If there has been a change of audio signal source 12, the process returns to block 104, where the audio signal source 12 is identified. If there has been no change in audio signal source 12, then the process returns to decision block 114, where the controller 16 decides whether there has been a manual adjustment of the output volume level through the volume selector 24.

In one illustrative embodiment, at optional process block 120, the controller 16 may modify the output volume level of the output device 18 in response to external conditions as detected by one or more of the external condition sensors 32. For example, the volume of the output device 18 may be adjusted based upon input from one or more of the signal strength sensor 32a, the vehicle speed sensor 32b, the location sensor 32c, and the time sensor 32d.

Turning now to FIG. 3, an illustrative volume setting sub-routine 116 is shown. When manual adjustment of the output volume level of the output device 18 is detected at block 114 (FIG. 2), the sub-routine 116 is initiated by starting the clock 28 at block 122. At decision block 124, the controller 16 queries whether the output volume level of the output device 18 has remained constant. If the output volume level of the output device 18 has not remained constant, then the process returns to block 122 where the clock 28 is restarted. If the output volume level has remained constant, then the process continues to decision block 126 where the controller 16 queries whether a predetermined time, as determined by the clock 28, has elapsed. More particularly, the controller 16 decides whether predetermined number of time increments have been counted by the clock 28. If a predetermined time has not elapsed, then the process returns to decision block 124. If a predetermined time has elapsed, then the process continues to decision block 128, where the controller 16 associates the adjusted output volume level of the output device 18 with the audio signal source 12, and then stores this combination as a stored volume setting.

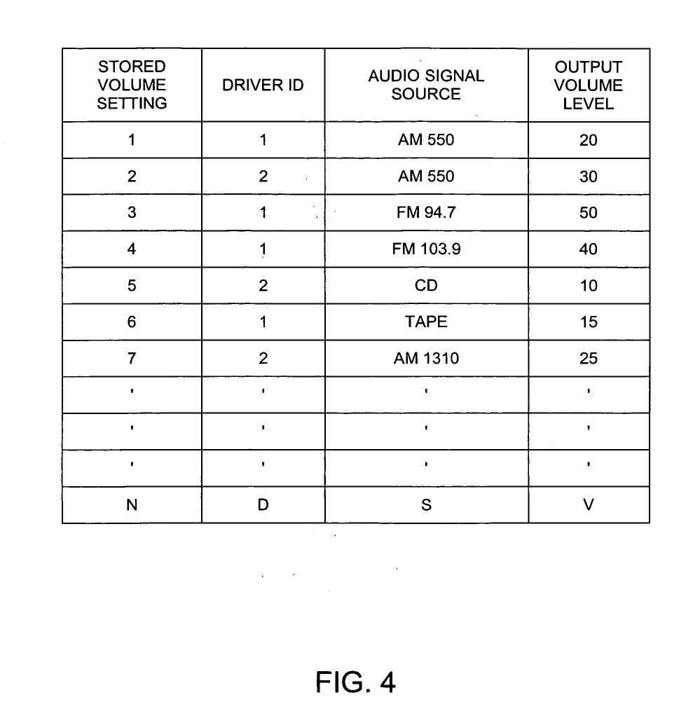

With reference to FIG. 4, an illustrative table shows various exemplary stored volume settings, which are stored in the memory 22. These stored volume settings may be distinguished based upon driver identification, and associate audio signal sources 12 with output volume levels. Moreover, each stored volume setting has a separate output volume level associated therewith. For example, stored volume setting 1 is indexed to driver ID 1, audio signal source radio frequency AM 550, and has an associated output volume level of 20. Stored volume setting 2 is indexed to driver ID 2, audio signal source radio frequency AM 550, and has an associated output volume level of 30. Stored volume setting 3 is associated with driver ID 1, audio signal source radio frequency FM 94.7, and has an output volume level of 50. Stored volume setting 4 is associated with driver ID 1, audio signal source radio frequency FM 103.90, and has an output volume level of 40. Stored volume setting 5 is indexed with driver ID 2, a CD player, and has an output volume level of 10. Stored volume setting 6 is associated with driver ID 1, a tape player, and has an output volume level of 15. Finally, stored volume setting 7 is associated with driver ID 2, audio signal source radio frequency AM 1310, and has an output volume level of 25.

As noted above, each of the output levels of the stored volume settings may be modified as appropriate based upon certain external conditions. Sensors 32 for detecting such external conditions are known in the art. Further, while it is envisioned that the present invention will have particular applicability with audio systems within vehicles, the volume control system of the present invention is not limited thereto and may be utilized with home audio systems, televisions, etc.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

1. An audio volume control system comprising:
an output device;
a plurality of audio signal sources;
a source selector coupled to the plurality of audio signal sources and configured to connect one of the audio signal sources to the output device in response to input from a user;
a controller coupled to the output device and configured to identify the audio signal source connected to the output device;
a memory configured to store the identity of the audio signal source connected to the output device and an output volume level of the output device, as a stored volume setting for the audio signal source; and
wherein the controller is further configured to retrieve the stored volume setting for the audio signal source, and control the output volume level of the output device in response to the stored volume setting.

2. The audio volume control system of claim 1, further comprising a volume selector configured to control the output volume level of the output device in response to input from a user.

3. The audio volume control system of claim 1, wherein each of the plurality of audio signal sources includes a common default output volume level.

4. The audio volume control system of claim 1, wherein each of the plurality of audio signal sources includes an initial default output volume level stored in the memory independent from other initial default output volume levels.

5. The audio volume control system of claim 1, further comprising a clock, wherein the controller is configured to associate the output volume level with the audio signal source, and store the stored volume setting in the memory after the clock has counted a predetermined number of increments.

6. The audio volume control system of claim 1, wherein the plurality of audio signal sources includes at least two of a compact disc player, a cassette tape player, and a radio frequency received by a tuner.

7. The audio volume control system of claim 1, wherein the plurality of audio signal sources includes a plurality of radio frequencies received by a tuner.

8. The audio volume control system of claim 1, further comprising at least one external condition sensor coupled to the controller and configured to detect conditions external to the audio signal source.

9. The audio volume control system of claim 8, wherein the external condition sensor comprises at least one of a radio frequency signal strength sensor, a vehicle speed sensor, a location sensor, and a time sensor.

10. An audio volume control system comprising:
an audio signal source;
a volume selector configured to control the output volume level from an audio signal supplied by the audio signal source in response to input from a user;
a processor configured to identify the audio signal source and the output volume level of the audio signal; and
a clock in communication with the processor, the processor being associate the output volume level of the audio signal with the audio signal source after the clock has counted a predetermined number of increments.

11. The audio volume control system of claim 10, further comprising an output device, and a source selector configured to connect one of a plurality of audio signal sources to the output device in response to input from a user.

12. The audio volume control system of claim 11, wherein the plurality of audio signal sources includes at least two of a compact disc player, a cassette tape player, and a radio frequency received by a tuner.

13. The audio volume control system of claim 11, wherein the plurality of audio signal sources includes a plurality of radio frequencies received by a tuner.

14. The audio volume control system of claim 10, further comprising a memory configured to store the identity of the audio signal source and the associated output volume level of the audio source as a stored volume setting.

15. The audio volume control system of claim 14, wherein the processor is further configured to control the output volume level in response to the stored volume setting.

16. The audio volume control system of claim 10, further comprising at least one external condition sensor coupled to the controller and configured to detect conditions external to the audio signal source.

17. A method of automatically controlling the volume produced by an audio system, the method comprising the steps of:
selecting a first audio signal source configured to generate a first audio signal;
identifying the first audio signal source;
controlling an output volume level of an output device in response to a first stored volume setting associating the first audio signal source with a first output volume level;
selecting a second audio signal source configured to generate a second audio signal;
identifying the second audio signal source; and
controlling an output volume level of the output device in response to a second stored volume setting associating the second audio signal source with a second output volume level.

18. The method of claim 17, further comprising the steps of:
manually adjusting the output volume level from the second audio signal source to an adjusted output volume level;
determining elapsed time of constant value for the adjusted output volume level;
associating the adjusted output volume level with the second audio signal source as a volume setting; and
storing the volume setting as the second stored volume setting after a predetermined elapsed time has passed.

19. The method of claim 17, further comprising the steps of:
detecting a condition external to the second audio signal source; and
adjusting the output volume level from the second audio signal source in response to the detected condition.

20. The method of claim 19, wherein the external condition comprises at least one of radio frequency signal strength, vehicle speed, location, and time.
